(19) United States
(12) Patent Application Publication
(10) Pub. No.: US 2013/0037712 A1
(43) Pub. Date: Feb. 14, 2013

(54) OPTICAL-CAVITY PHASE PLATE FOR TRANSMISSION ELECTRON MICROSCOPY

(71) Applicants: Robert GLAESER, Berkeley, CA (US); Jian Jin, Berkeley, CA (US); Radostin Danev, Germany (DE); Holger Mueller, Orinda, CA (US); John Spence, Temple, AZ (US)

(72) Inventors: Robert GLAESER, Berkeley, CA (US); Jian Jin, Berkeley, CA (US); Radostin Danev, Germany (DE); Holger Mueller, Orinda, CA (US); John Spence, Temple, AZ (US)

(73) Assignee: REGENTS OF THE UNIVERSITY OF CALIFORNIA, Oakland, CA (US)

(21) Appl. No.: 13/487,831

(22) Filed: Jun. 4, 2012

Related U.S. Application Data
(63) Continuation of application No. PCT/US2010/059103, filed on Dec. 6, 2010.
(60) Provisional application No. 61/267,348, filed on Dec. 7, 2009.

(51) Int. Cl. H01J 37/22

(52) U.S. Cl. 250/307; 250/311

(57) ABSTRACT

An optical phase plate system and method for enhancing phase contrast in electron beam imaging includes a transmission electron microscope (TEM) having a back focal plane; an optical cavity having a high internal surface reflectance, the center of the optical cavity located at the back focal plane of the TEM, the optical cavity having first and second ports arranged oppositely along a symmetrical axis of the optical cavity to admit an electron beam provided by the TEM through the first port to pass through and focus at the center of the optical cavity, and to exit through the second port, and wherein the optical cavity further has an optical port on an axis transverse to and intersecting the electron beam axis to admit a laser beam; a laser coupled to the optical cavity to provide a laser beam of a selected wavelength to enter the optical cavity through the optical port, wherein the laser beam is multiply reflected from the high internal surface reflectance to provide a high intensity standing wave optical phase plate focused at the back focal plane of the TEM to cause a modulation of the electron beam; and an image plane of the TEM placed opposite the second port of the optical cavity to receive the electron beam modulated by the high intensity standing wave optical phase plate.

### CROSS-REFERENCE TO RELATED APPLICATIONS

This application is a continuation of PCT International Application No. PCT/US2010/059103 entitled “OPTICAL-CAVITY PHASE PLATE FOR TRANSMISSION ELECTRON MICROSCOPY” and filed Dec. 6, 2010, which claims priority to U.S. Provisional Patent Application No. 61/267,348 to Robert Glaser et al. entitled “OPTICAL-CAVITY PHASE PLATE FOR TRANSMISSION ELECTRON MICROSCOPY” and filed Dec. 7, 2009, both of which applications are hereby incorporated by reference in their entirety.

### STATEMENT OF GOVERNMENTAL SUPPORT

This invention was made in the course of or under prime contract No. DE-ACO2-05CH11231 between the Department of Energy and the University of California, and prime contract No. DE-FG03-02ER45996. The government has certain rights in this invention.

### TECHNICAL FIELD

This disclosure relates to transmission electron microscopy (TEM), and more particularly to phase contrast enhancement in TEMs for imaging macromolecules using an intensely focused standing wave laser beam.

### BACKGROUND

Modern transmission electron microscopes have become powerful imaging tools that achieve a resolution about a thousand times higher than light microscopes; yet, their imaging performance for thin biological specimens remains relatively poor: Such specimens are weakly scattering “phase objects,” i.e., they show virtually no absorption of the impinging electrons. As a result, the intensity of the transmitted electron beam remains equal to that of the incident beam, and a perfect image of such objects shows no contrast. Historically, electron microscopes have thus required special preparation of samples in which heavy-metal “staining” provides contrast. These procedures are difficult and time-consuming; moreover, they have been known to alter the structures and thus limit the resolution at which meaningful information can be obtained.

Even for unstained phase objects, the object (specimen) structure is imprinted on the phase of the matter wave describing the transmitted electrons. As discovered for optical microscopes by Zernike [Zernike 1955], this invisible phase modulation can be converted into visible amplitude contrast. The light that passes a specimen is decomposed into an undiffracted component and a diffracted component. The undiffracted light is focused to a bright spot at the center of this plane by an objective lens. The diffracted light is arranged around this center. Diffraction by fine structures of the object leads to a larger diffraction angle. Hence, the diffraction orders that correspond to fine details of the image (i.e., having small dimensions) lie far away from the center, whereas large-scale structures cause diffracted light near the center. Mathematically, the intensity distribution in this back focal plane is given by a spatial Fourier transform of the specimen's transmission, which is referred to as the Fourier transform plane.

If the specimen is a pure phase object, there is a special phase relationship between these components. By offsetting this phase relationship, the phase modulation is converted into amplitude modulation. Maximum conversion, and thus maximum phase contrast, is obtained with a phase shift of 90 degrees, or π/2. In optics, this is done by a phase plate, which is essentially a glass plate coated so that light passing through a small area in the middle receives an extra phase shift.

Unfortunately, no simple phase plates exist for electron beams, making it hard to view unstained biological specimens. A partial solution is given by cryo-electron microscopy methods. These avoid staining and the associated generation of structural artifacts and generate a certain amount of phase contrast by intentionally viewing the specimens in an out-of-focus condition combined with intentional spherical aberration [Lentzen 2004]. By optimizing the tradeoff between the phase distortion due to defocus and that due to spherical aberration, one can achieve the desired conversion of phase into amplitude contrast. However, the phase shifts vary continuously over the spectrum of spatial frequencies. As a result, this “simple” method works well for small features in the image, but contrast for larger features is lost. Since it is necessary to have substantial contrast for large features, too, in order to see biological macromolecules, it is often necessary to use a much larger amount of defocus. Unfortunately, this results in reduced resolution. Also, the contrast transfer function oscillates multiple times in the region of higher spatial frequencies. Defocus is thus an imperfect way to produce phase contrast in images of biological macromolecules.

Nagayama and Danev, in Okazaki, Japan, have developed a thin carbon film as a phase plate in transmission electron microscopy [Danev & Nagayama, 2001; Hosokawa et al., 2005; Nagayama & Danev, 2008]. The thickness of the film causes the scattered electrons to experience a π/2 phase shift, whereas the axial electrons pass through a 1 μm diameter central hole. The main disadvantage of this technology is that these phase plates “age” on a time scale of days or weeks. It is also very difficult to fabricate them reproducibly. In addition, a fraction of the useful signal is lost when the scattered electrons pass through the thin carbon film.

More recently, microfabrication techniques have allowed for the construction of electron microscope phase plates [Cambie et al., 2007] following an early proposal by Boersch [Boersch 1947]. The focused, undiffracted beam is passed through a small hole in an electrode that is biased by tens to hundreds of millivolt, depending upon the particular electrode geometry in the device, thereby resulting in the desired phase shift. Electrostatic shielding of the electrode prevents interaction with the scattered electrons, so that they experience no additional phase.

Another embodiment of a phase plate [Nagayama & Danev, 2009] uses a long, very thin bar magnet that is placed across the electron diffraction pattern, closely adjacent to the undiffracted electron beam. A phase shift is generated by the Aharonov-Bohm effect because of the difference in the magnetic vector potential on either side of the long bar magnet.

All such efforts are currently limited by the short time that it takes for a physical device to become electrically charged, presumably due to a build-up of contamination on the surface when the device is hit by an intense electron beam. This causes unwanted electric fields, which lead to an uncontrolled phase shift in the electron beam at various scattering angles. This effectively makes the images irreproducible and un-interpretable. Also, the electrode blocks the diffracted beams closest to the center, thus reducing the contrast for large structures in the image. Similar problems are faced by thin film phase plates.

### DESCRIPTION OF THE FIGURES

For a more complete understanding of the present disclosure, reference is now made to the following description taken in conjunction with the accompanying drawings.

FIG. 1 shows one embodiment of a transmission electron microscope including an optical-cavity phase plate according to an embodiment of the disclosure.

FIG. 2 shows an intensity pattern of a resonant optical-cavity phase plate according to an embodiment of the disclosure.

FIG. 3 shows a system for generating an optical-phase plate for modulating the phase of an electron beam according to an embodiment of the disclosure.

### DETAILED DESCRIPTION

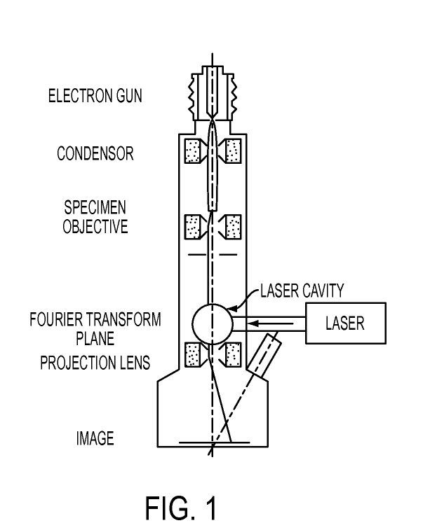

In an embodiment, a strong electric field in a tightly focused laser beam forms a phase plate (FIG. 1). The phase plate, inserted into the Fourier transform plane (i.e., the back focal plane) of the electron microscope, consists of an intense focused laser beam. A nearly spherical resonant optical cavity is used to shape the focus and to further enhance the laser beam phase plate intensity. The electron beam travels through holes at opposite ends of the spherical cavity (e.g., on top and bottom). The interaction of the laser beam's intense electric field with the charge of the electrons creates a phase-shift in the electron beam, which corresponds to an increase of an “optical path length” of the electrons, which may be visualized as wiggling the electron trajectory to increase the path distance traveled. If the increase is ¼ of the electrons' de Broglie wavelength, the desired π/2 phase shift is achieved.

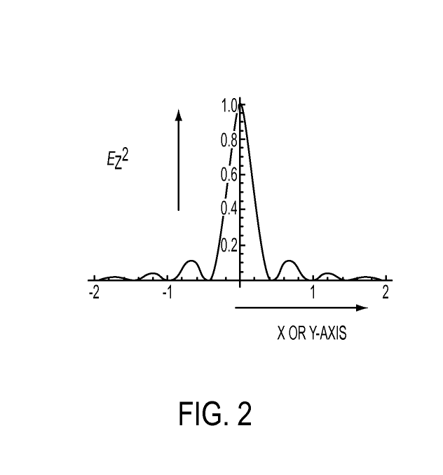

Resonant enhancement of the laser beam in the spherical optical cavity alleviates the high power optical beam requirements. This provides a narrow intensity maximum at the center (about 0.5 wavelengths radius, as shown in FIG. 2), which is a good match to the size of the undiffracted electron beam in the Fourier transform plane. Electrons outside the center see a comparatively low electric field and experience negligible phase shift.

In a simple classical model, the laser's action as a phase plate is because the alternating electric field of the laser wiggles the trajectories of the electrons and thus increases their path length. A quantum mechanical treatment [Dawson & Fried, 1967] shows that the phase shift is

$$δ = \frac{h αρλτ}{m} . \qquad ( 1 )$$

Here, is the reduced Planck constant, α the fine structure constant, ρ the density of photons, γ the laser wavelength, τ the time it takes the electrons to traverse the focus, and m the electron mass. Away from the optical focal point at the center of the cavity the photon density ρ drops rapidly, so that there is no significant phase shift other than at the optical focus. We can express the photon density ρ=4P/(π²c²γ) by the laser power P, where c is the velocity of light. We have assumed that the electric field has a Gaussian intensity profile with an 1/e² intensity “waist” radius of wₒ=γ/2, which is a good approximation for the intensity distribution inside the cavity. This is the smallest focus that can be obtained for a laser of given wavelength; a larger focus is possible but result in higher required laser power. For estimating the transit time τ, we can use the same model to obtain τ=γ/vₑ, where vₑ is the electron beam velocity. A more accurate estimate, which takes into account the actual intensity distribution of the cavity (FIG. 2), is τ=sqrt(π/2)γ/vₑ. Inserting into Eq. (1), the phase is

$$δ = \sqrt{\frac{8}{{π}^{3}}} \frac{αλ P}{{mv}_{e} {c}^{2}} . \qquad ( 2 )$$

The laser phase plate has the property that almost no electrons are lost when traversing the phase plate: Only about one electron in a million will be lost by Compton scattering with the photons.

Equation (2) can be used to calculate the laser power P required to generate a δ=π/2 phase shift as a function of electron velocity and laser wavelength. The electron velocity vₑ for a 100 keV electron microscope is approximately 10⁸ m/s.

According to Eq. (2), the desired π/2 phase shift is dependent on the product of laser wavelength and laser beam power. It is desirable to work with the lowest possible laser power P, which can be traded off with a larger laser wavelength λ.

Conversely, the laser wavelength determines the size of the laser focus, which has to match the size of the undiffracted electron beam. In particular, if the focus is too large, a loss of contrast for larger structures in the specimen results. For example consider the tobacco mosaic virus, which is rod-shaped with a diameter of d=18 nm. Obtaining the full amount of contrast over this diameter requires phase contrast for spatial frequencies up to 1/(2 d)=1/(36 nm). For example, the electron optical focal length in the an electron microscope (e.g., FEI Titan, available from FEI Company, 5350 NE Dawson Creek Drive, Hillsboro, Oreg. 97124) is f=20 mm and the electron wavelength λₑ is 3.7 pico meters (pm) at 100 keV. Resolving spatial frequencies of 1/(36 nm) will lead to a maximum phase plate radius on the order of f λₑ/(2d)=20 mm×36 nm/(3.7 pm)˜2 μm, i.e., a maximum wavelength of ˜4 μm.

High-power lasers at this wavelength are hard to obtain. Selection of a laser wavelength is also constrained by the availability of reliable commercial high-power lasers. For example, according to Eq (2) a laser wavelength of 1064 nm requires about 5 kW of laser power to generate the required π/2 phase shift for a 100 keV electron beam. At this wavelength, a radius of the optical beam focus of about 0.5 μm is obtained. This would enable phase contrast for structures sized up to 80 nm, satisfying the above requirements.

Pulsed lasers can easily achieve kW-level power for durations of nanoseconds (ns), but their use would require pulsing the electron beam as well. Such pulsing, however, is not available in most commercial TEM devices. Most importantly, however, cathode current density limitations in the electron gun introduce new complications in the operation of an electron microscope in a pulsing mode. Therefore, a continuous wave high intensity optical field is desirable.

The intensity of the laser beam may be increased by use of an optical cavity to obtain resonant enhancement. In such a cavity, the laser radiation is bouncing back and forth between the cavity mirrors. If the laser wavelength is an half-integer multiple of the mirror separation, the radiation on all round-trips adds constructively, providing resonant intensity enhancement. This happens when the radiation has one of the resonance frequencies

$${f}_{n} = \frac{nc}{2 L} , \qquad ( 3 )$$

where n=1,2,3, . . . is a mode number (this equation holds to sufficient accuracy of the cavity when length L is much larger than the wavelength). For resonant laser light, the intensity will be increased by a factor of
where R is the reflectivity of the mirror. A perfect reflector would have a value of R=1.

1/(1−R), (4)

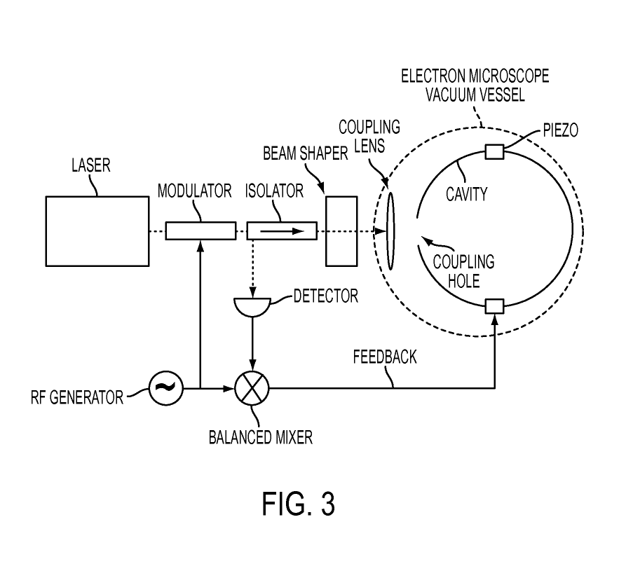

Besides intensity enhancement, the cavity has to provide a very tight focus of the laser beam. A tightly focused beam diverges quickly, i.e., requires optics with a large numerical aperture (NA). The smallest focus, therefore, results from the strongly divergent transverse electromagnetic mode TEMn01 in a spherical cavity that encloses the optical beam completely (FIGS. 2, 3). The electromagnetic field in a strongly focused beam is nontrivial [Lekner 2003; Lindfors et al., 2007]. Use of this spherical cavity has the additional advantage that the electric field in such a spherical cavity is known from analytical calculations [Zhang & Li, 2007].

Referring to FIG. 1, The optical cavity may be arranged, for example, with the electron beam going vertically downwards (e.g., along a z-axis), entering the cavity through a hole at the top and exiting through another hole at the bottom. The laser beam is shown as pointing horizontally and may have its polarization orthogonal to the plane of the figure. The electric field far away from the center of the optical cavity is zero on a circle in the x-y plane that includes the top and bottom of the cavity. Thus, the holes for the electron beam will not lead to appreciable loss of optical power: These holes are large enough in order not to inhibit the flow of electrons, e.g., a radius of about 1 mm, but which may be larger or smaller. If the cavity radius is 10 mm or larger, these holes will dissipate no more than 0.01% of the cavity's circulating power. Moreover, this allows constructing the cavity out of two hollow hemispheres, joined after manufacturing to make a single sphere. They are joined in the plane of vanishing electric field, so that even an imperfect joint will lead to no appreciable loss of optical power.

The intensity enhancement factor is set by the reflectivity of the mirror surfaces, i.e., the high internal surface reflectance. With dielectric coatings, a reflectivity of R=99.99% and larger, corresponding to an intensity increase by factors of 10,000 and larger, is state of the art. Unfortunately, however, dielectric coatings require a precise thickness, which is difficult to achieve on highly curved surfaces such as the two hemispheres, but may eventually be achievable. Metal-coated mirrors are easier to fabricate, as the thickness of the coatings is unimportant. Metal reflectivity at 1 micron of 99% is conventionally available, providing power enhancement by a factor of 100. This may be sufficient with available state of the art high-power lasers.

In an embodiment, the required power can be reduced by increasing the wavelength, but this will increase the spot size. At a C0₂ laser wavelength of 10 μm, the power circulating in the cavity need only be 500 W for a π/2 phase shift, and the power enhancement factor with metallic mirrors would be about 200. Thus, only 2.5 W of laser power would be required. With a ˜5 μm size focal point, some loss in contrast for large scale features of the specimen would occur, as discussed above. Still, such a configuration would be simpler in terms of needed laser power.

The cavity may be made by joining two hemispheres with a radius of, for example, 8-10 mm. The size is primarily determined by the space that is available in the electron microscope for placement of the phase plate. The hemispheres may be ground into a quadratic shape in a block of beryllium-copper for good thermal conductivity and mechanical stability or, alternatively, Invar™ for low thermal expansion. It is noted that maintaining exactly spherical shape is of secondary importance, as the cavity may be deliberately distorted anyway, as described below. The hemispheres are polished to λ/10 and coated with gold on the inside. Because of the relatively high losses of the gold minors, a better polish is not necessary. The hemispheres may be attached to each other by one or more piezoelectric transducer (PZT) to tune the optical-cavity for frequency stabilization at one optical frequency, while suppressing other competing modes that may result in phase gratings of different standing wave period intensities. Laser power on the order of 50 W will dissipate on the cavity walls. The heat may be carried away by liquid cooling. For a temperature rise of 10 C (easily satisfied with liquid cooling) the 10-mm radius hemispheres expand by roughly 160 nm for BeCu or 16 nm for Invar™. This will lead to a shift in the resonance frequency which has to be compensated for by active feedback (described below). In addition to this, the dynamic range of the PZT must at least be half a laser wavelength to allow for obtaining resonance at any laser frequency (see Eq. (3)). A gold surface at λ=1 μm has R=0.99, achieving a power enhancement factor of 100. From Eqs. (2,3) and assuming a 75% power transmission from the laser to the cavity, a 67 W laser would be required. A single frequency fiber laser currently available from IPG photonics (50 Old Webster Road, Oxford Mass. 01540) provides a 50 W laser at this wavelength. Since the phase contrast varies as the sine of the phase shift, and thus as the sine of the laser power, >90% of the optimum phase contrast is obtainable with a 50 W laser. A higher-power laser would enable working with a lower cavity coupling efficiency, lowering the cost of fabricating the optical cavity.

To efficiently couple the laser radiation into the cavity, it is desirable to obtain a nearly spherically symmetric mode from a directed laser beam. This is because besides the desired resonant mode with the tightest focus (FIG. 2), the cavity can resonate in a large number of other modes due to the spherical symmetry. For an exact sphere, many of these modes have the same resonance frequency as the desired mode. Therefore, distorting the cavity slightly, which can be done simply by adjusting the distance between the half spheres, breaks the degeneracy of the cavity modes, i.e., the desired mode now has a distinct resonance frequency. If the laser radiation has this frequency, it will predominantly excite this mode. Other modes that would resonate at different frequencies are rendered cavity non-resonant and are thus suppressed.

FIG. 3 shows a system for generating a an optical phase plate for modulating the phase of an electron beam. Coupling the laser beam can be achieved simply via a hole of radius rᵢₙ in the cavity. The transmission of power from the laser into the cavity mode is optimized when it balances the losses in the other parts of the cavity (i.e., losses due to finite reflectivity of the metal surfaces). For the desired resonant mode shown in FIG. 2, this condition is satisfied if 1=(2/3)(4r_{cav}²/rᵢₙ²) (1−R), where r_{cav} is the radius of the cavity, and R the reflectivity of the cavity's minor, or rᵢₙ/r_{cav}=[8(1−R)/3]^{1/2}=0.16 for R=0.99.

Even if this condition is satisfied, the coupling efficiency may still not be 100%. Consider a time-reversed situation where the cavity generates light, which exits through the coupler. The coupler is small compared to the size of the TEMn01 mode resonating inside the cavity. Thus, the electric field exiting through the coupler has a nearly uniform intensity over the diameter of the coupler and is nearly zero outside (neglecting diffraction at the edge, which is reasonable because the coupler's radius is much larger than the wavelength, therefore diffraction effects are substantially negligible). By time reversal, this defines the required shape of a laser beam impinging the cavity that has optimum power transfer. The laser, however, produces a Gaussian mode. The optimum power transfer between a Gaussian mode and the truncated (‘top hat”) cavity mode is 50.4% and occurs when the waist radius parameter of the Gaussian beam at the plane of the coupler is equal to the radius of the coupler. It also assumes a coupling lens of appropriate focal length. This efficiency can be improved to theoretically 100% by transforming the Gaussian beam into a uniform-intensity beam using a beam shaping apparatus, which is basically a phase grating. Such techniques with 84-90% efficiency have been reported [Matizen & Troitskii, 1989; Palima & Gliickstad, 2008].

In order for the cavity to provide maximum intensity enhancement, the laser's frequency must match one of the resonances of the cavity. To obtain resonance in spite of thermal and other drifts in the laser and cavity, a feedback mechanism based on the Pound-Drever-Hall method is used [Dreyer et al., 1983] (as shown in FIG. 3). For this purpose, an electro optic modulator applies phase modulation with a frequency ωₘ and a modulation index βₘ to the laser beam. The beam is coupled to the cavity and a reflected signal due to radiation exiting from the optical cavity is detected. An isolator may be used to couple the reflected signal to the detector. In another embodiment, beam splitters and minors may be used to couple the reflected signal to the detector. The resonant properties of the cavity convert the phase modulation into amplitude modulation. When the laser and the resonance frequency coincide, the detected reflected component of the amplitude modulation reaches a minimum, ideally vanishing; otherwise, a nonzero AM occurs. It is detected by amplitude and phase using a double-balanced mixer (DBM), who's output is lowpass filtered to suppress the modulation frequency ωₘ. This leads to a signal with a zero phase crossing at resonance. This signal is fed back to the laser frequency actuator via a suitable servo that keeps the cavity resonance aligned to the laser. Because of the high signal power in this system, a very slight modulation may be sufficient to obtain a feedback signal of high signal-to-noise ratio.

Numerous methods of use and applications may be considered. In biochemistry, major improvements may be realized in determining the structures of multiprotein complexes and macromolecular machines. In cell biology, major improvements may be realized in localizing such complexes and their spatial relationships within whole cells by EM tomography. In both cases, Zernike phase contrast is expected to improve the ability to image unstained specimens that are embedded in vitreous ice, i.e. in a life-like state.

In an embodiment, a method of use includes recording images of biological macromolecules and supramolecular structures. Such study requires obtaining the maximum image contrast that is physically possible. Compared with present defocus methods to image unstained samples in TEMs, the contrast of the in-focus Zernike optical cavity phase contrast microscope may be as much as a factor of ten greater (see above), and would not degrade or corrupt the signal at high resolution, as does the use of defocus.

In addition to the biological applications, in an embodiment, the microstructure of soft materials can be characterized.

In an embodiment, the optical cavity phase plate can be applied to generate a 3-dimensional optical trap of extreme depth. Trap depths can be in the range of tens or even hundreds of Kelvin, trapping, for example room-temperature atoms and localizing them in space to better than 0.5 microns, even for species for which cooling is difficult. Such traps are be useful for a wide range of atoms or molecules, as the huge intensity in the cavity will make it unimportant to align the laser frequency closely to an atomic or molecular transition. This allows spectroscopy of very weak transitions for such atoms. An example is the nuclear spectroscopy of Thorium 229 atom with lasers. Laser spectroscopy of the ˜5-6 eV transition in the Thorium 229 nucleus can be a breakthrough in precision measurements, as it allows for building “nuclear” clocks that are based on a transition between nuclear energy levels rather than those in the electron shells. It has, however, been hampered by lack of a suitable method for localizing the atoms. Only with localized atoms can the probe laser be focused tightly as required to generate sufficient intensity. The dipole trap proposed here can solve this problem and enable direct laser spectroscopy of the transition. This can lead to higher precision clocks (as the nucleus is less sensitive to the environment), as well as tests of the time variability of fundamental “constants” with unprecedented accuracy.

Providing a dielectric coating technology capable of fabricating uniformly controllable dielectric layers mirrors on high NA-cavity interior surfaces enables higher resonance enhancement, and thus allows use of lower cost lower power lasers, or longer laser wavelengths (which would enable use of a lower NA cavity).

Compared to the conventional microstructured phase plates mentioned above, it may be appreciated that the resonant optical cavity phase plate has several advantages: It does not use any mechanical electrodes inside the electron beam; the optical elements required to bring in the laser beam can be sufficiently far away (1 mm or more) so that problems with blurring and distorting the images are avoided; it overcomes the problems of short device life time, which currently limits the performance of the thin-film type of phase plate; it overcomes the problem of partial loss of scattered electrons, which occurs for both thin-film phase plates and electrostatic or magnetic phase plates; and it will make electron microscopy more productive and more efficient because it does not generate a partial loss of signal and because there are no interruptions caused by the need to replace a microstructure or thin-film phase plate that had aged or that had become contaminated when hit by the electron beam.

By converting phase into amplitude contrast, resonant optical cavity phase TEM may capture meaningful signals from very small amounts of unstained, and therefore unaltered, material. This method is thus useful to all research programs that use the electron microscope to determine the structure of unstained biological materials, or low atomic-number materials in general, including organic polymers and other soft materials. These programs include biology and materials science research, medical schools, private research institutes, or chemical companies developing new polymer materials. Usage is likely to also grow to include research laboratories in the biotech and pharmaceutical sector.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the embodiments of the present disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

### BIBLIOGRAPHY AND REFERENCES CITED

Boersch, H., 1947. Z. Naturforsch. 2A (1947) 615.
Cambie, R., Downing, K. H., Typke, D., Glaeser, R. M., and Jin J., 2007. Design of a microfabricated, two-electrode phase-contrast element suitable for electron microscopy. Ultramicroscopy 107, 329-339.
Danev R. and Nagayama K., 2001. Transmission electron microscopy with Zernike phase plate. Ultramicroscopy 88, 243-252.
Dawson, J. F., and Fried, Z., 1967. Electron interference effects induced by laser light. Phys. Rev. Lett. 19, 467.
Dreyer, R. W. P., Hall, J. L., Kowalski, F. V., Hough, J., Ford, G. M., Munley, A. J., and Ward, H. 1983. Laser phase and frequency stabilization using an optical resonator. Appl. Phys. B, 31, 97-105.
Gamm, B., Schultheiβ, K., Gerthsen, D., and Schroder, R. R., 2007. Effect of a physical phase plate on contrast transfer in an aberration-corrected transmission electron microscope. Ultramicroscopy 108, 878.
Gerike, T., Urtz, P. W., Reitz, D., Langen, T., and Ott, H. 2008. High-resolution scanning electron microscopy of an ultracold quantum gas. Nature Phys. 4, 40.
Hosokawa, F., Danev, R., Arai, Y., Nagayama, K., 2005. Transfer doublet and an elaborated phase plate holder for 120 kV electron-phase microscope. J. Electron Microscopy 54, 317-324.
Lentzen, M., 2004. The tuning of a Zernike phase plate with defocus and variable spherical aberration and its use in HRTEM imaging. Ultramicroscopy 99, 211-220.
Lekner, J. 2003. Polarization of tightly focused laser beams. J. Opt. A 5, 6-14.
Lindfors, K., Priimagi, A., Setala, T., Shevchenko, A., Friberg, A. T., and Kaivola, M. 2007.
Local polarization of tightly focused unpolarized light. Nature photonics 1, 228.
Majorovits, E., Barton, B., Schultheiβ, K., Pérez-Willard, F., Gerthsen, D., Schröder, R., 2007.
Achieving optimized phase contrast electron microscopy with an electrostatic Boersch phase plate. Ultramicroscopy 107, 213.
Matizen, Y. and Troitskii, Y. V., 1989. Formation of a laser beam with a uniform intensity distribution utilizing an intracavity inhomogeneous beam splitter. Soy. J. Quantum Electron. 19, 398-402.
Nagayama, K. and Danev, R., 2008. Phase contrast electron microscopy: development of thinfilm phase plates and biological applications. Philos. Trans. R. Soc. London B 363, 2153-2162.
Nagayama, K. and Danev, R., 2009. Phase-plate electron microscopy: a novel imaging tool to reveal close-to-life nano-structures, Biophys. Rev. 1, 37-42.
Palima, D., and Glückstad, J. 2008. Gaussian to uniform intensity shaper based on generalized phase contrast. Opt. Express, 16, 1507-1516.
Schultheiβ, K., Pérez-Willard, F., Barton, B., Gerthsen, D., and Schröder, R. R., 2006.
Fabrication of a Boersch phase plate for phase contrast imaging in a transmission electron microscope. Rev. Sci. Instr. 77, 033701.
Shu, G., Dietrich, M. R., Kurz N., and Blinov, B. B., 2009. Trapped ion imaging with a high numerical aperture spherical mirror. J. Phys. B: 42, 154005.
Zernike, F. 1955. How I discovered phase contrast. Science 121, 345-349.
Zhang, K., Li, D., 2007. Electromagnetic Theory for Microwaves and Optoelectronics. (Springer,Berlin).

What is claimed is:

1. An optical phase plate system for enhancing phase contrast in electron beam imaging comprising:
a transmission electron microscope (TEM) having a back focal plane;
an optical cavity having a high internal surface reflectance, the center of the optical cavity located at the back focal plane of the TEM, the optical cavity having first and second ports arranged oppositely along a symmetrical axis of the optical cavity to admit an electron beam provided by the TEM through the first port to pass through and focus at the center of the optical cavity, and to exit through the second port, and wherein the optical cavity further has an optical port on an axis transverse to and intersecting the electron beam axis to admit a laser beam;
a laser coupled to the optical cavity to provide a laser beam of a selected wavelength to enter the optical cavity through the optical port, wherein the laser beam is multiply reflected from the high internal surface reflectance to provide a high intensity standing wave optical phase plate focused at the back focal plane of the TEM to cause a modulation of the electron beam; and
an image plane of the TEM placed opposite the second port of the optical cavity to receive the electron beam modulated by the high intensity standing wave optical phase plate.

2. The optical phase plate system of claim 1, wherein the high internal reflectance is approximately 0.99 or greater.

3. The optical phase plate system of claim 1, wherein the optical cavity comprises:
a cavity of substantially spherical curvature.

4. The optical phase plate system of claim 3, wherein the substantially spherical cavity is comprised of two substantially hemispherical concave cavity segments.

5. The optical phase plate system of claim 4, wherein the two substantially hemispherical cavities are joined in a plane perpendicular to the electron beam axis.

6. The optical phase plate system of claim 3, wherein the two substantially hemispherical cavities are joined by one or more piezoelectric transducers to adjust a separation of the two substantially hemispherical cavities.

7. The optical phase plate system of claim 6, further comprising:
an electro optic phase modulator coupled to the laser to phase modulate the laser beam output by a radio frequency (RF) generator at a frequency ωₘ and a modulation index βₘ;
a beam shaper to receive and alter an intensity distribution of the phase modulated laser beam;
a lens to receive the phase modulated and intensity distribution altered laser beam for coupling to the optical cavity through the optical port;
an isolator to direct at least a portion of optical radiation exiting the optical cavity to a detector; and
a double balanced mixer coupled to the RF generator and the detector to detect an amplitude and a phase in a signal output by the detector and to output a signal on the basis of the detected amplitude and phase to control the piezoelectric transducers.

8. A method of enhancing phase contrast in an electron beam image comprising:
providing a transmission electron microscope (TEM) having a back focal plane, wherein the electron beam includes a first component undiffracted by a specimen and a second component diffracted by the specimen;
positioning a center of an optical cavity having a high internal surface reflectance at the TEM back focal plane;
admitting the electron beam through a first port of the optical cavity along a symmetrical axis through the center of the optical cavity;
exiting the electron beam through a second port of the optical cavity along the symmetrical axis;
admitting a laser beam of a selected wavelength to an optical port of the optical cavity, the optical port arranged on an axis transverse to and intersecting the electron beam axis, wherein the laser beam is multiply reflected from the high internal surface reflectance to provide a high intensity standing wave optical phase plate focused at the back focal plane of the TEM to cause a modulation of the electron beam; and
imaging the electron beam in an image plane of the TEM placed opposite the second port of the optical cavity to receive the electron beam modulated by the high intensity standing wave optical phase plate.

9. The method of claim 8, further comprising providing the high internal reflectance to have a value of approximately 0.99 or greater.

10. The method of claim 8, further comprising:
forming the interior surface of the optical cavity to have a substantially spherical curvature.

11. The method of claim 10, further comprising:
forming the optical cavity with two substantially hemispherical concave cavity segments joined to form the substantially spherically curved cavity.

12. The method of claim 11, further comprising:
joining the two substantially hemispherical cavities in a plane perpendicular to the electron beam axis.

13. The method of claim 11, further comprising:
joining the two substantially hemispherical cavities by one or more piezoelectric transducers to adjust a separation of the two substantially hemispherical cavities.

14. The method of claim 13, further comprising:
phase modulating the laser beam by a radio frequency (RF) generator at a frequency ωₘ and a modulation index βₘ;
shaping the phase modulated laser beam to alter an intensity distribution of the laser beam;
coupling with a lens the phase modulated and intensity distribution altered laser beam to the optical cavity through the optical port;
directing to a detector at least a portion of optical radiation exiting the optical cavity;
detecting an amplitude and a phase in a signal output by the detector and outputting a signal on the basis of the detected amplitude and phase; and
controlling the piezoelectric transducers to tune the optical cavity on the basis of the signal output from the detector on the basis of the detected amplitude and phase.
